(19) United States
(12) Patent Application Publication
(10) Pub. No.: US 2023/0332326 A1
(43) Pub. Date: Oct. 19, 2023

(54) INGOT GROWTH APPARATUS AND CONTROL METHOD THEREOF

(71) Applicants: HANWHA SOLUTIONS CORPORATION, Seoul (KR); HANWHA CORPORATION, Seoul (KR)

(72) Inventors: Jin Sung PARK, Seoul (KR); Kyung Seok LEE, Seoul (KR); Young Jun LEE, Sejong-si (KR); Keun Ho KIM, Seoul (KR)

(73) Assignees: HANWHA SOLUTIONS CORPORATION, Seoul (KR); HANWHA CORPORATION, Seoul (KR)

(21) Appl. No.: 18/028,815

(22) PCT Filed: Sep. 3, 2021
(86) PCT No.: PCT/KR2021/011942

§ 371 Date: Mar. 28, 2023

(30) Foreign Application Priority Data
Sep. 28, 2020 (KR) 10-2020-0126318

(51) Int. Cl. C30B 15/20; C30B 29/06; C30B 15/00; C30B 15/28

(52) U.S. Cl. CPC C30B 15/20; C30B 29/06; C30B 15/002; C30B 15/28

(57) ABSTRACT

Disclosed is an ingot growing apparatus. The ingot growing apparatus according to the embodiment of the present invention includes a growth furnace in which a main crucible is disposed, wherein the main crucible accommodates molten silicon to grow an ingot, a preliminary crucible which receives a solid silicon material, melts the solid silicon material, and supplies molten silicon to the main crucible, a measurement unit which is installed to pass through the growth furnace and measures a change in level of the surface of the molten silicon in the main crucible, and a control unit which controls supply of the molten silicon in the preliminary crucible to the main crucible on the basis of the measured change in the level of the surface of the molten silicon.

### CROSS-REFERENCE TO RELATED APPLICATION

This application claims priority to and the benefit of Korean Patent Application No. 200X-XXXXX, filed on XXX X, 200X, the disclosure of which is incorporated herein by reference in its entirety.

### BACKGROUND

### 1. Field of the Invention

The present invention relates to an ingot growing apparatus and a method of controlling the same.

### 2. Discussion of Related Art

Single-crystal silicon is used as a basic material for most semiconductor devices, and such materials are manufactured as single crystals having high purity. One such manufacturing method is the Czochralski method.

In the Czochralski method, a solid silicon material is input to a crucible in a chamber, and a susceptor is heated using a heating element to melt silicon. In addition, when a single crystal seed is moved upward and rotated at the same time using a wire in a state in which the single crystal seed is in contact with the molten silicon, an ingot having a predetermined diameter is grown through a crown process of increasing a diameter to a target diameter of the ingot.

A continuous Czochralski (CCz) method, which is one such Czochralski method, is a method of continuously growing an ingot while replenishing consumed molten silicon in a crucible by continuously injecting solid polysilicon or molten silicon into the crucible.

However, when the crucible is replenished with a smaller or larger amount than the molten silicon consumed due to the growth of the ingot, a level of a surface of the molten silicon is lowered or raised, and thus there is a problem that the ingot cannot be grown any more.

In addition, when the crucible is replenished with a smaller or larger amount than the molten silicon consumed due to the growth of the ingot, it is difficult to maintain the level of the surface of the molten silicon at a target level, and thus there is a problem in controlling a diameter of the ingot causing a decrease in yield and degradation of quality.

### SUMMARY OF THE INVENTION

The present invention is directed to providing an ingot growing apparatus capable of maintaining a constant level of a surface of molten silicon by supplying consumed molten silicon even when molten silicon accommodated in a crucible is consumed due to the growth of an ingot, and a method of controlling the same.

In addition, the present invention is directed to providing an ingot growing apparatus capable of managing predetermined levels of quality and yield of an ingot, and a method of controlling the same.

According to an aspect of the present invention, there is provided an ingot growing apparatus including a growth furnace in which a main crucible is disposed, wherein the main crucible accommodates molten silicon to grow an ingot, a preliminary crucible which receives a solid silicon material, melts the solid silicon material, and supplies molten silicon to the main crucible, a measurement unit which is installed to pass through the growth furnace and measures a change in level of a surface of the molten silicon in the main crucible, and a control unit which controls supply of the molten silicon in the preliminary crucible to the main crucible on the basis of the measured change in the level of the surface of the molten silicon.

A reflector which blocks heat from being transferred to the ingot may be provided at an upper side of the main crucible, and the measurement unit may measure the change in the level of the surface of the molten silicon through a change in gap between the surface of the molten silicon in the main crucible and a lower end of the reflector by measuring the surface of the molten silicon of the main crucible and the lower end of the reflector.

The control unit may calculate a change in level of the surface of the molten silicon in the main crucible on the basis of a diameter of the ingot, an upward pulling speed of the ingot, and a diameter of the main crucible.

When the measured change in the level of the surface of the molten silicon is greater than the calculated change in the level of the surface of the molten silicon, the control unit may increase the molten silicon in the preliminary crucible supplied to the main crucible as much as a difference between the measured change in the level of the surface of the molten silicon and the calculated change in the level of the surface of the molten silicon.

When the measured change in the level of the surface of the molten silicon is smaller than the calculated change in the level of the surface of the molten silicon, the control unit may decrease the molten silicon in the preliminary crucible supplied to the main crucible as much as a difference between the measured change in the level of the surface of the molten silicon and the calculated change in the level of the surface of the molten silicon.

When the surface of the molten silicon comes into contact with the lower end of the reflector, the control unit may stop supplying the molten silicon in the preliminary crucible to the main crucible.

The ingot growing apparatus may further include a weight measurement unit which measures a change in weight of the ingot per unit time, wherein the control unit may calculate a change in weight of the ingot per unit time on the basis of the diameter of the ingot and the upward pulling speed of the ingot, and when the measured change in the weight of the ingot per unit time is greater than the calculated change in the weight of the ingot per unit time, the control unit may increase the molten silicon in the preliminary crucible supplied to the main crucible as much as a difference between the measured change in the weight of the ingot per unit time and the calculated change in the weight of the ingot per unit time.

According to another aspect of the present invention, there is provided a method of controlling an ingot growing apparatus in which molten silicon in a preliminary crucible is supplied to a main crucible in which an ingot is grown, the method including a surface level change measurement operation in which a change in level of a surface of molten silicon in a main crucible is measured and a molten silicon supply control operation in which supply of molten silicon in a preliminary crucible to the main crucible is controlled on the basis of the measured change in the level of the surface of the molten silicon.

In the surface level change measurement operation, the change in the level of the surface of the molten silicon may be measured through a change in distance between the surface of the molten silicon in the main crucible and a lower end of a reflector provided above the main crucible by measuring the surface of the molten silicon of the main crucible and the lower end of the reflector.

The method of controlling the ingot growing apparatus may further include a surface level change calculation operation in which a change in level of the surface of the molten silicon in the main crucible is calculated on the basis of a diameter of the ingot, an upward pulling speed of the ingot, and a diameter of the main crucible.

The molten silicon supply control operation may include a first supply increase operation in which the molten silicon in the preliminary crucible supplied to the main crucible is increased as much as a difference between the measured change in the level of the surface of the molten silicon and the calculated change in the level of the surface of the molten silicon when the measured change in the level of the surface of the molten silicon is greater than the calculated change in the level of the surface of the molten silicon.

The molten silicon supply control operation may include a supply reduction operation in which the molten silicon in the preliminary crucible supplied to the main crucible is reduced as much as a difference between the measured change in the level of the surface of the molten silicon and the calculated change in the level of the surface of the molten silicon when the measured change in the level of the surface of the molten silicon is smaller than the calculated change in the level of the surface of the molten silicon.

The molten silicon supply control operation may include a supply stop operation in which the supply of the molten silicon in the preliminary crucible to the main crucible is stopped when the surface of the molten silicon comes into contact with the lower end of the reflector.

The method of controlling the ingot growing apparatus may further include an ingot weight change measurement operation in which a change in weight of the ingot per unit time is measured and an ingot weight change calculation operation in which a change in weight of the ingot per unit time is calculated on the basis of the diameter of the ingot and the upward pulling speed of the ingot, wherein in the molten silicon supply control operation, the supply of the molten silicon in the preliminary crucible to the main crucible may be controlled on the basis of the measured change in the level of the surface of the molten silicon, the calculated change in the level of the surface of the molten silicon, the measured change in the weight of the ingot per unit time, and the calculated change in the weight of the ingot per unit time.

The molten silicon supply control operation may include a second supply increase operation in which the molten silicon in the preliminary crucible supplied to the main crucible is increased as much as a difference between the measured change in the weight of the ingot per unit time and the calculated change in the weight of the ingot per unit time when the measured change in the weight of the ingot per unit time is greater than the calculated change in the weight of the ingot per unit time.

The method of controlling the ingot growing apparatus may further include a power energy reduction operation in which power energy for heating the preliminary crucible is reduced when the supply of the molten silicon is reduced.

The method of controlling the ingot growing apparatus may further include a molten silicon supply operation in which a required amount of a solid silicon material is melted and the molten silicon in the preliminary crucible is supplied to the main crucible a plurality times.

The method of controlling the ingot growing apparatus may further include a molten silicon accommodation maintenance operation in which a state in which a predetermined amount or more of the molten silicon is accommodated in the preliminary crucible is maintained.

### BRIEF DESCRIPTION OF THE DRAWINGS

Not only detailed descriptions of exemplary embodiments of the present invention described below but also the summary described above will be understood more easily when read with reference to the accompanying drawings. The exemplary embodiments are illustrated in the drawings to illustrate the present invention. However, it should be understood that the present invention is not limited to the exact layout and method illustrated in the drawings, in which:

FIG. 1 is a schematic view illustrating an ingot growing apparatus according to an embodiment of the present invention;

FIG. 2 is a block diagram illustrating the ingot growing apparatus according to the embodiment of the present invention;

FIG. 3 is a view illustrating a first position and a second position of a preliminary crucible illustrated in FIG. 1;

FIG. 4 is a flowchart illustrating a method of controlling an ingot growing apparatus according to the embodiment of the present invention;

FIG. 5 is a flowchart specifically illustrating a molten silicon supply control operation of FIG. 4;

FIG. 6 is a flowchart specifically illustrating a method of controlling supply of molten silicon according to a change in weight of an ingot;

FIG. 7 is a table showing a melting time of molten silicon in the preliminary crucible according to adjustment of power supply; and

FIG. 8 is a view illustrating a supply pattern (feeding sequence) of a solid silicon material in a quantitative supply unit (bucket feeding) and a supply pattern (feeding sequence) of molten silicon in the preliminary crucible (MP feeding) supplied to a main crucible.

### DETAILED DESCRIPTION OF EXEMPLARY EMBODIMENTS

Terms and words used in this specification and claims should not be interpreted as limited to commonly used meanings or meanings in dictionaries and should be interpreted with meanings and concepts which are consistent with the technological scope of the present invention based on the principle which the inventors have appropriately defined concepts of terms in order to describe the invention in the best way.

Therefore, since the embodiments described in this specification and configurations illustrated in the accompanying drawings are only exemplary embodiments and do not represent the overall technological scope of the invention, the corresponding configurations may have various equivalents and modifications which can substitute for the configurations at the time of filing of this application.

It should be understood which the terms “comprise,” “include,” or the like, when used herein, specify the presence of stated features, numbers, operations, elements, components, or groups thereof but do not preclude the presence or addition of one or more other features, numbers, operations, elements, components, or groups thereof.

Unless there are special circumstances, a case in which a component is disposed “in front of,” “behind,” “above,” or “under” another component includes not only a case in which the component is disposed directly “in front of,” “behind,” “above,” or “under” another component, but also a case in which still another component is interposed therebetween. Unless there are special circumstances, a case in which some components are connected to each other includes not only a case in which the components are directly connected to each other, but also a case in which the components are indirectly connected to each other.

Hereinafter, an ingot growing apparatus according to an embodiment of the present invention will be described with reference to the accompanying drawings. In describing the ingot growing apparatus according to the embodiment of the present invention, components which are not related to a content of the invention will not be illustrated in detail or will be omitted for simplification of the accompanying drawings, and the ingot growing apparatus according to the present invention will be described mainly based on the content related to the spirit of the invention.

In this specification, an arrow direction of a Z axis is referred to as an upward direction of a growth furnace. A downward direction is an opposite direction of the upward direction.

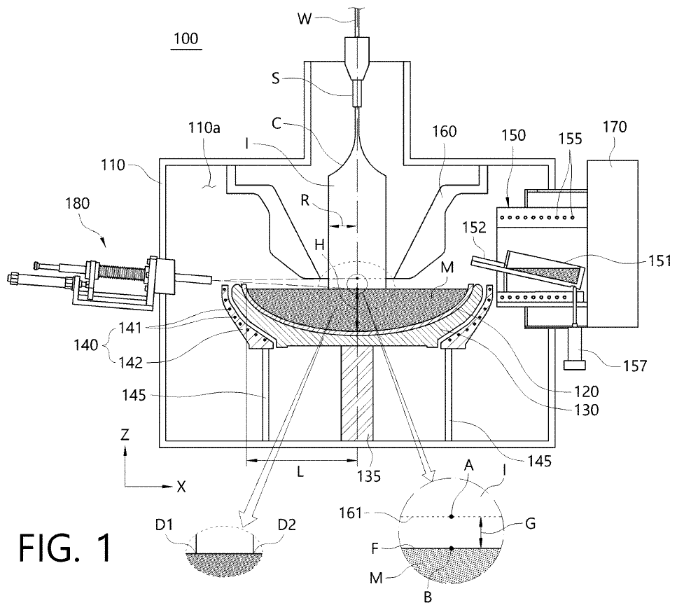

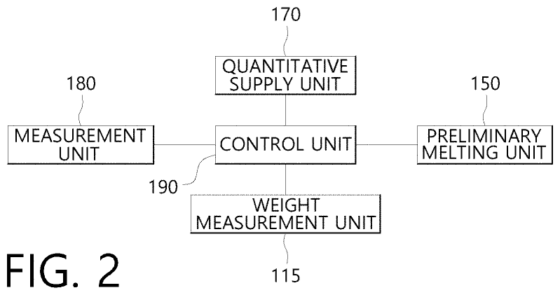

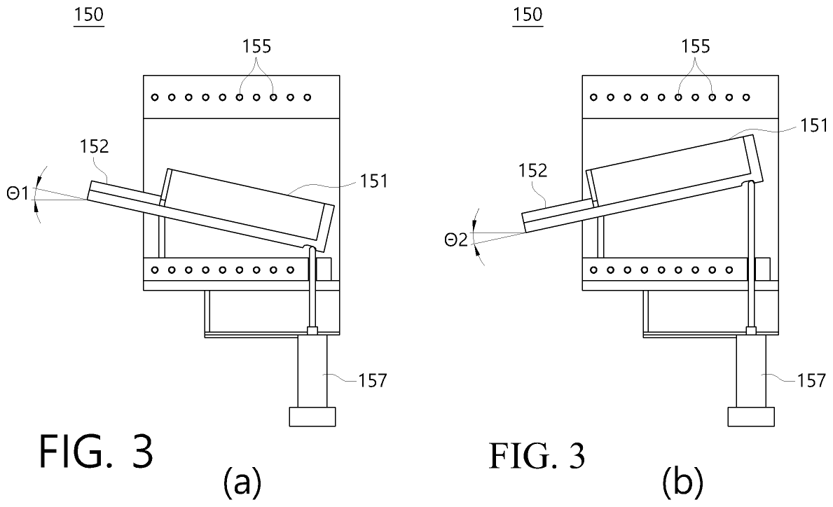

FIG. 1 is a schematic view illustrating an ingot growing apparatus according to an embodiment of the present invention, FIG. 2 is a block diagram illustrating the ingot growing apparatus according to the embodiment of the present invention, and FIG. 3 is a view illustrating a first position and a second position of a preliminary crucible illustrated in FIG. 1.

Referring to FIGS. 1 to 3, an ingot growing apparatus 100 according to the embodiment of the present invention includes a growth furnace 110, a main crucible 120, a preliminary melting unit 150, a measurement unit 180, and a control unit 190.

The growth furnace 110 is formed to have an inner space 110a maintained in a vacuum state, and an ingot I is grown in the inner space 110a. The main crucible 120, which will be described below, is disposed in the inner space 110a.

The growth furnace 110 includes a vacuum pump (not shown) and an inert gas supply unit (not shown). The vacuum pump may maintain the inner space 110a in a vacuum atmosphere. In addition, the inert gas supply unit supplies an inert gas to the inner space 110a. The inert gas may be, for example, argon (Ar).

The main crucible 120 is accommodated in the inner space 110a of the growth furnace 110. The main crucible 120 may accommodate molten silicon M. In addition, the main crucible 120 is generally formed in a reverse dome shape. In addition, the main crucible 120 is not limited to being formed in the reverse dome shape and may be formed in various shapes such as a cylindrical shape.

In addition, an inner diameter L of the main crucible 120 is defined based on a portion in which the molten silicon M is in contact with an inner surface of the main crucible 120.

In addition, the main crucible 120 is formed of a quartz material. However, the main crucible 120 is not limited to being formed of the quartz material and may be formed of any material which has heat resistance at a temperature of about 1400° C. or higher and withstands a sudden change in temperature.

In addition, in a state in which a single crystal seed S is in contact with the molten silicon M contained in the main crucible 120, when a wire W connected to an upper side of the growth furnace 110 pulls the single crystal seed S in an upward direction (Z axis), the ingot I having a predetermined diameter R is grown in the direction (Z axis) in which the ingot I is pulled upward through a crown C process of increasing a diameter of an ingot to a target diameter of the ingot I.

The growth furnace 110 includes a susceptor 130 formed to surround an outer surface of the main crucible 120. The susceptor 130 supports the main crucible 120. An inner surface of the susceptor 130 is formed in a shape corresponding to the outer surface of the main crucible 120. For example, when the main crucible 120 has the reverse dome shape, the susceptor 130 also has a reverse dome shape. The susceptor 130 is formed of a graphite material. In addition, the susceptor 130 is not limited to being formed of the graphite material and may be formed of any material having high heat resistance and conductivity.

Accordingly, even when the main crucible 120 is formed of the quartz material and deformed at a high temperature, the susceptor 130 surrounds and supports the main crucible 120 to maintain a state in which the main crucible 120 accommodates the molten silicon M.

In addition, a susceptor support 135 which supports the susceptor 130 is disposed on a lower surface of the growth furnace 110. An upper end of the susceptor support 135 is formed in a shape corresponding to a lower end of the susceptor 130. In addition, in a state in which the susceptor support 135 supports the susceptor 130 at a lower side of the growth furnace 110, the susceptor support 135 is rotated with the susceptor 130. Accordingly, in a state in which the main crucible 120 accommodates the molten silicon M, the main crucible 120 is rotated with the susceptor 130.

In addition, the growth furnace 110 includes a driving unit (not shown) which provides a rotational force to rotate the susceptor support 135. The susceptor support 135 is rotatably connected to the driving unit. When the driving unit receives power and provides a rotational force to the susceptor support 135, the main crucible 120 is rotated with the susceptor 130.

In addition, the growth furnace 110 includes a heater 140 which heats the susceptor 130. The heater 140 includes a coil 141 which receives power to generate a magnetic field and a shield 142 which surrounds the coil 141.

The coil 141 is formed to surround an outer surface of the susceptor 130. The coil 141 receives the power to generate the magnetic field. In addition, a current is generated in the susceptor 130 due to electromagnetic induction of the magnetic field of the coil 141. In this case, the current generated in the susceptor 130 is converted into thermal energy. Accordingly, the heater 140 heats the susceptor 130. Heat of the susceptor 130 is thermally conducted to the main crucible 120, and thus the susceptor 130 heats the main crucible 120.

The shield 142 supports the coil 141 to maintain a predetermined shape of the coil 141. The shield 142 is formed of a ceramic. The shield 142 prevents the coil 141 from being exposed to the inner space 110a of the growth furnace 110. Accordingly, since the shield 142 prevents the coil 141 from being exposed to the inner space 110a of the growth furnace 110, when the coil 141 receives the power to generate the magnetic field, generation of an arc discharge due to a plasma phenomenon in the vacuum state is prevented, or generation of an arc discharge caused by the coil coming into contact with the inert gas (for example, argon) present in the inner space 110a is prevented.

In addition, the heater 140 is not limited to operating in an induction heating manner and may operate in a resistance heating manner which receives power to be directly heated.

In addition, a heater support 145 which supports the heater 140 is disposed at a lower side of the growth furnace 110. The heater support 145 is formed in a substantially cylindrical shape. The susceptor support 135 is disposed in the heater support 145 formed in the cylindrical shape. In addition, an upper end of the heater support 145 is formed in a shape corresponding to a lower end of the heater 140, and thus the heater 140 is disposed on the upper end of the heater support 145.

The preliminary melting unit 150 receives a solid silicon material and melts the solid silicon material into molten silicon. In addition, the preliminary melting unit 150 includes a preliminary crucible 151 which accommodates the molten silicon.

In addition, the preliminary crucible 151 is formed of a quartz material. However, the preliminary crucible 151 is not limited to being formed of the quartz material and may be formed of any material which has heat resistance at a temperature of about 1400° C. or higher and withstands a sudden change in temperature.

In addition, the preliminary crucible 151 includes a beak 152 extending toward the main crucible 120. The molten silicon accommodated in the preliminary crucible 151 is supplied to the main crucible 120 through the beak 152.

The preliminary crucible 151 is provided to be positioned between a first position at which the preliminary crucible 151 accommodates and melts the accommodated solid silicon material and which is illustrated in FIG. 3(a) and a second position at which the preliminary crucible 151 is tilted to supply the molten silicon to the main crucible 120 and which is illustrated in FIG. 3(b).

To this end, the preliminary melting unit 150 includes a preliminary crucible moving module 157 which moves a position of the preliminary crucible 151.

The preliminary crucible moving module 157 tilts one side of the preliminary crucible 151 toward the main crucible 120 to supply the molten silicon accommodated in the preliminary crucible 151 to the main crucible 120. In this case, a side of the preliminary melting unit 150 facing the main crucible 120 is referred to as one side, and an opposite side is referred to as the other side. When the preliminary crucible 151 is tilted at the second position, the molten silicon in the preliminary crucible 151 falls into the main crucible 120 through one side of the preliminary crucible 151.

In addition, the preliminary melting unit 150 includes a preliminary heater 155 which melts the solid silicon material supplied to the preliminary crucible 151. The preliminary heater 155 operates in an induction heating manner. In addition, the preliminary heater 155 may also operate in a resistance heating manner.

In addition, a quantitative supply unit 170 which supplies the solid silicon material to the preliminary crucible 151 is provided outside the growth furnace 110.

The quantitative supply unit 170 measures a weight of the solid silicon material. In addition, the quantitative supply unit 170 supplies a required amount of the solid silicon material to the preliminary crucible 151.

In addition, the growth furnace 110 includes a reflector 160 positioned above the main crucible 120.

The reflector 160 is formed in a shape which surrounds the ingot I. That is, the ingot I is disposed in the reflector 160. The reflector 160 serves to block heat of the main crucible 120 from being transferred to the ingot I. The reflector 160 is formed of a graphite material.

In addition, a lower end 161 of the reflector 160 is disposed to be spaced apart from a surface F of the molten silicon M accommodated in the main crucible 120. That is, a gap G is provided between the lower end 161 of the reflector 160 and the surface F of the molten silicon M.

The measurement unit 180 is installed to pass through a sidewall of the growth furnace 110. The measurement unit 180 measures a change in level of the surface F of the molten silicon M of the main crucible 120 and the diameter of the ingot I.

In this case, the measurement unit 180 measures a first point A of the lower end 161 of the reflector 160. The measurement unit 180 measures a second point B of the surface F of the molten silicon M of the main crucible 120. In this case, the second point B is positioned in a downward direction (Z axis) of the first point A.

In addition, a change in the gap G between the first point A and the second point B is the same as a change in level H of the surface F of the molten silicon M. That is, when the measurement unit 180 measures the change in the gap G, the change in the level H of the surface F of the molten silicon M may be known.

In addition, the diameter of the ingot may be measured by measuring a first point D1 and a second point D2 which are contact points between an outermost point of the ingot and the surface F of the molten silicon illustrated in FIG. 1.

In addition, as illustrated in FIG. 2, the control unit 190 is electrically connected to components provided in the growth furnace 110. For example, the control unit 190 is electrically connected to the preliminary melting unit 150, the quantitative supply unit 170, the measurement unit 180, and a weight measurement unit 115 which measures a weight of the ingot I.

In this case, the control unit 190 receives a value of the measured change in the level H of the surface F of the molten silicon M from the measurement unit 180. The control unit 190 controls an amount of the molten silicon in the preliminary crucible 151 supplied to the main crucible 120 on the basis of the measured value of the change in the level H of the surface F of the molten silicon M.

Accordingly, a constant level H of the surface F of the molten silicon M in the main crucible 120 can be maintained by controlling supply of the molten silicon supplied to the main crucible 120 according to the change in the level H of the surface F of the molten silicon M measured in real time.

A method of controlling supply of molten silicon by the control unit 190 will be described in detail with reference to the accompanying drawings.

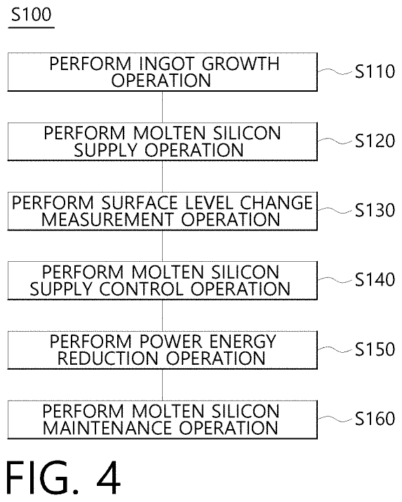

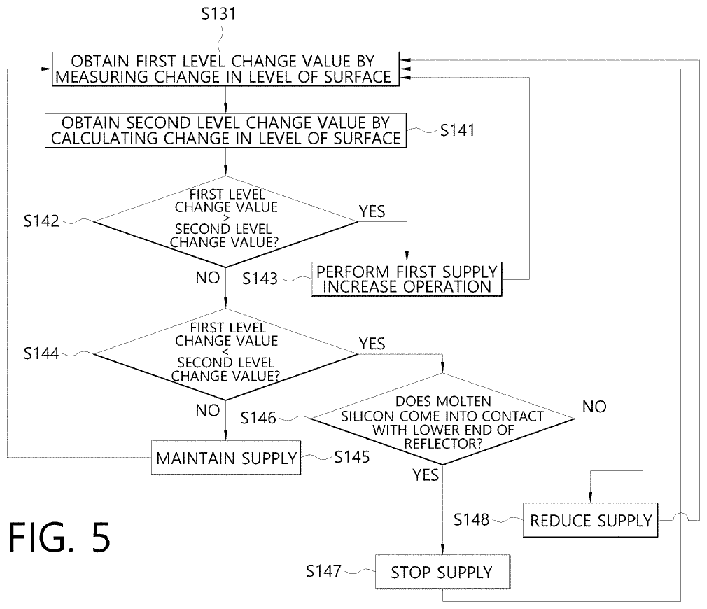

FIG. 4 is a flowchart illustrating a method of controlling the ingot growing apparatus according to the embodiment of the present invention, and FIG. 5 is a flowchart specifically illustrating a molten silicon supply control operation of FIG. 4.

First, as illustrated in FIG. 4, a method S100 of controlling the ingot growing apparatus according to the embodiment of the present invention includes an ingot growth operation S110, a molten silicon supply operation S120, a surface level change measurement operation S130, and a molten silicon supply control operation S140.

In the ingot growth operation S110, the ingot I (see FIG. 1) is pulled upward (Z axis, see FIG. 1) and grown using the molten silicon M (see FIG. 1) accommodated in the main crucible 20. For example, an upward pulling speed of the ingot I (see FIG. 1) is about 2 mm/min. In addition, the diameter of the ingot is about 216 mm. However, the upward pulling speed and the diameter of the ingot are not limited thereto and may be variously applied according to process conditions.

In the molten silicon supply operation S120, the molten silicon accommodated in the preliminary crucible 151 (see FIG. 1) is supplied to the main crucible 120 (see FIG. 1). In this case, one side of the preliminary crucible 151 (see FIG. 1) is positioned at the second position at which the preliminary crucible 151 is tilted toward the main crucible 120 (see FIG. 1), and the main crucible 120 (see FIG. 1) is replenished with the molten silicon.

In addition, in the molten silicon supply operation S120, a required amount of a solid silicon material is melted, and the molten silicon in the preliminary crucible 151 (see FIG. 1) is supplied to the main crucible 120 (see FIG. 1) a plurality of times.

In the surface level change measurement operation S130, a change in the gap G (see FIG. 1) between the first point A (see FIG. 1) and the second point B (see FIG. 1) is measured by measuring the second point B (see FIG. 1) of the surface F of the molten silicon M based on the first point A (see FIG. 1) of the lower end 161 (see FIG. 1) of the reflector 160 (see FIG. 1). The change in the gap G (see FIG. 1) is the same as a change in the level H of the surface of the molten silicon.

In this case, as illustrated in FIG. 5, the surface level change measurement operation S130 includes an operation S131 of obtaining a first level change value obtained by measuring the change in the level H of the surface of the molten silicon. In this case, the first level change value means the change in the level of the surface of the molten silicon measured by the measurement unit 180 (see FIG. 1).

In the molten silicon supply control operation S140, supply of the molten silicon in the preliminary crucible 151 (see FIG. 1) to the main crucible 120 (see FIG. 1) is controlled by the control unit 190 (see FIG. 1) on the basis of the measured change in the level of the surface of the molten silicon M.

In this case, as illustrated in FIG. 5, the molten silicon supply control operation S140 includes an operation S141 of obtaining a second level change value, an operation S142 of determining whether the first level change value is greater than the second level change value, a first supply increase operation S143 of supplying the molten silicon, an operation S144 of determining whether the first level change value is smaller than the second level change value, a molten silicon supply maintenance operation S145, an operation S146 of determining whether the molten silicon comes into contact with the lower end of the reflector, a molten silicon stop operation S147, and a molten silicon supply reduction operation S148.

In the operation S141 of obtaining the second level change value, a change in the level of the surface of the molten silicon of the main crucible 120 (see FIG. 1, H,1) is calculated by the control unit 190 (see FIG. 2) on the basis of the diameter of the ingot I (see FIG. 1), the upward pulling speed of the ingot I (see FIG. 1), and a diameter of the main crucible 120 (see FIG. 1). In this case, the second level change value means the change in the level of the surface of the molten silicon accommodated in the main crucible obtained by calculating an amount of the molten silicon consumed due to the growth of the ingot. That is, the second level change value refers to the calculated change in the level of the surface of the molten silicon.

In this case, when the diameter of the ingot is 216 mm, the upward pulling speed of the ingot is 2 mm/min, and the diameter of the main crucible is 680 mm, a weight of the molten silicon (ingot Wt.) consumed due to the growth of the ingot is calculated as follows. In this case, the weight of the molten silicon (ingot Wt.) consumed due to the growth of the ingot is a weight of molten silicon to be supplied to the main crucible.

$$Ingot Wt . = ( {( \frac{216 mm}{2} )}^{2} \times π \times 2 mm / min \times 2.33 g / {cm}^{3} ) / 1000 = 170.6 g / min$$

In addition, the second level change value (a change in level of molten silicon in a crucible) in consideration of the weight of the molten silicon (Ingot Wt.) consumed due to the growth of the ingot is calculated as follows.

$$Change in level of surface of molten silicon in crucible = Ingot Wt . / ( {( \frac{680 mm}{2} )}^{2} \times π \times 2.54 g / {cm}^{3} ) / 1000 ) = 0.185 mm$$

That is, the second level change value is about 0.185 mm.

The operation S142 of determining whether the first level change value is greater than the second level change value is performed by the control unit 190 (see FIG. 2). When the first level change value is greater than the second level change value, the control unit 190 (see FIG. 2) performs the first supply increase operation S143 which will be described below. Conversely, when the first level change value is not greater than the second level change value, the control unit 190 (see FIG. 2) performs the operation S144 of determining whether the first level change value, which will be described below, is smaller than the second level change value.

In the first supply increase operation S143, an increasing amount α of the molten silicon corresponding to a difference between the first level change value and the second level change value is supplied to the main crucible by the control unit 190 (see FIG. 2). For example, the control unit 190 (see FIG. 2) supplies the increasing amount α to the main crucible in addition to 170.6 g/min corresponding to a weight of the molten silicon (Ingot Wt.) consumed due to the growth of the ingot.

The operation S144 of determining whether the first level change value is smaller than the second level change value is performed by the control unit 190 (see FIG. 2). When the first level change value is smaller than the second level change value, the control unit 190 (see FIG. 2) performs the operation (S146) of determining whether the molten silicon, which will be described below, comes into contact with the lower end of the reflector. Conversely, when the first level change value is not smaller than the second level change value, the control unit 190 (see FIG. 2) performs the molten silicon supply maintenance operation S145 which will be described below.

In the molten silicon supply maintenance operation S145, for example, the molten silicon is supplied to the main crucible at a constant rate of 170.6 g/min.

The operation S146 of determining whether the molten silicon comes into contact with the lower end of the reflector is performed by the control unit 190 (see FIG. 2). When the molten silicon comes into contact with the lower end of the reflector, the control unit 190 (see FIG. 2) performs the molten silicon stop operation S147. When the molten silicon does not come into the lower end of the reflector, the control unit 190 (see FIG. 2) performs the molten silicon supply reduction operation S148.

In the molten silicon stop operation S147, the preliminary crucible is controlled by the control unit 190 (see FIG. 2) to be moved to the first position to stop supplying the molten silicon to the main crucible. Accordingly, the molten silicon is prevented from being excessively supplied to the main crucible to secure stability of a single crystal growth process of the ingot.

In the supply reduction operation S148, a decreasing amount β of the molten silicon corresponding to a difference between the first level change value and the second level change value is subtracted from supply to the main crucible by the control unit 190 (see FIG. 2). For example, the control unit 190 (see FIG. 2) subtracts the decreasing amount β from 170.6 g/min corresponding to the weight of the molten silicon (Ingot Wt.) consumed due to the growth of the ingot and supplies the molten silicon to the main crucible.

In addition, according to the embodiment of the present invention, the control unit 190 (see FIG. 2) performs the first supply increase operation S143, the supply maintenance operation S145, the silicon stop operation S147, and the supply reduction operation S148, and then performs the operations illustrated in FIG. 5 from the first level change value obtaining operation 131 again to control the supply of the molten silicon in real time.

In addition, the method S100 of controlling the ingot growing apparatus according to the embodiment of the present invention includes a power energy reduction operation S150 and a molten silicon accommodation maintenance operation S160 which will be described below with reference to the accompanying drawings.

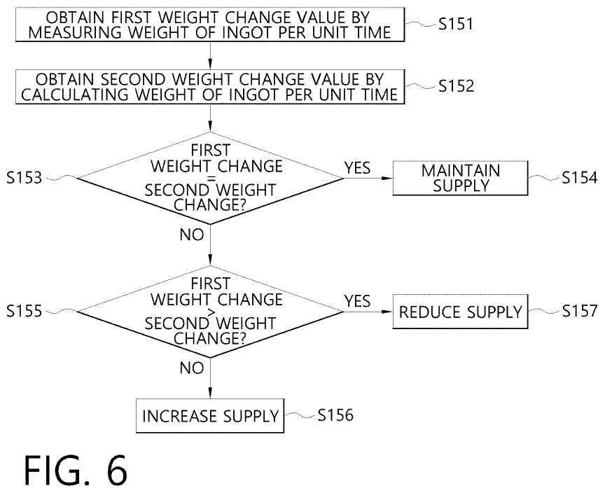

FIG. 6 is a flowchart specifically illustrating a method of controlling supply of molten silicon according to a change in weight of an ingot;

A method of precisely controlling supply of molten silicon by feeding a change in weight of an ingot back to a change in level of a surface of molten silicon described above will be described.

Referring to FIG. 6, the method S100 (see FIG. 5) of controlling the ingot growing apparatus according to the embodiment of the present invention includes an ingot weight change measurement operation S151, an ingot weight change calculation operation S152, an operation S153 of determining whether a first weight change value and a second weight change value are the same, a supply maintenance operation S154, an operation S155 of determining whether the first weight change value is greater than the second weight change value, a second supply reduction operation S156, and a second supply increase operation S157.

In the ingot weight change measurement operation S151, a change in weight of the ingot per unit time is measured by the weight measurement unit 115 (see FIG. 2). In this case, the measured change in the weight of the ingot per unit time is referred to as the first weight change value.

In the ingot weight change calculation operation S152, a weight of the molten silicon (Ingot Wt.) consumed due to the growth of the ingot is calculated as described above. In this case, the weight of the molten silicon (Ingot Wt.) consumed due to the growth of the ingot means the calculated change in the weight of the ingot per unit time. In this case, the calculated change in the weight of the ingot per unit time is referred to as the second weight change value. For example, the second weight change value is about 170.6 g/min as described above.

The operation S153 of determining whether the first weight change value and the second weight change value are the same is performed by the control unit 190 (see FIG. 2). When the first weight change value is the same as the second weight change value, the control unit 190 (see FIG. 2) performs the supply maintenance operation S154. Conversely, when the first weight change value is not the same as the second weight change value, the control unit 190 (see FIG. 2) performs the operation S155 of determining whether the first weight change value is greater than the second weight change value.

In the supply maintenance operation S154, for example, the molten silicon is supplied to the main crucible at a constant rate of 170.6 g/min.

The operation S155 of determining whether the first weight change value is greater than the second weight change value is performed by the control unit 190 (see FIG. 2). When the first weight change value is greater than the second weight change value, the control unit 190 (see FIG. 2) performs the second supply increase operation S157. Conversely, when the first weight change value is not greater than the second weight change value, the control unit 190 (see FIG. 2) performs the second supply reduction operation S156.

In the second supply increase operation S157, a second increasing amount α2 of the molten silicon corresponding to a difference between the first weight change value and the second weight change value is supplied to main crucible by the control unit 190 (see FIG. 2). For example, the control unit 190 (see FIG. 2) supplies the second increasing amount α2 to the main crucible in addition to 170.6 g/min corresponding to the weight of the molten silicon (Ingot Wt.) consumed due to the growth of the ingot. In addition, according to various examples of the present invention, the control unit 190 (see FIG. 2) may more precisely adjust the increasing amount α according to the change in the level of the surface in consideration of the second increasing amount α2.

In the second supply reduction operation S156, the control unit 190 (see FIG. 2) subtracts a second decreasing amount α2 of the molten silicon corresponding to a difference between the first weight change value and the second weight change value from the supply to the main crucible. For example, the control unit 190 (see FIG. 2) subtracts the second decreasing amount α from 170.6 g/min corresponding to the weight of the molten silicon (Ingot Wt.) consumed due to the growth of the ingot when the molten silicon is supplied to the main crucible. In addition, according to various embodiments of the present invention, the control unit 190 (see FIG. 2) may more precisely adjust the decreasing amount a according to the change in the level of the surface in consideration of the second decreasing amount α2.

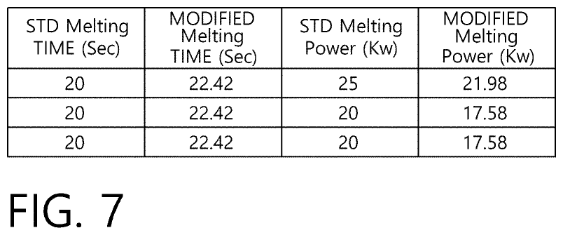

FIG. 7 is a table showing a melting time of molten silicon in the preliminary crucible according to adjustment of power supply.

Referring to FIG. 7, a method of controlling consumption of power energy for melting a solid silicon material in the preliminary crucible according to an increase or decrease in supply amount of molten silicon supplied to the main crucible 120 (see FIG. 1) will be described.

Meanwhile, the control unit 190 (see FIG. 2) controls the quantitative supply unit 170 (see FIG. 1) to supply a required amount of a solid silicon material stored in the quantitative supply unit 170 (see FIG. 1) to the preliminary crucible 151 (see FIG. 1).

The preliminary crucible 151 (see FIG. 1) receives the solid silicon material and is heated by the preliminary heater 155 (see FIG. 1) so that the solid silicon material is converted into molten silicon. In this case, when high power energy is supplied to the preliminary heater 155 (see FIG. 1), a time for melting the solid silicon material is reduced, and when low power energy is supplied thereto, the time for melting the solid silicon material is increased.

The method of controlling the ingot growing apparatus according to the embodiment of the present invention includes the power energy reduction operation S150 which reduces power energy for heating the preliminary crucible when the supply of the molten silicon is reduced.

That is, when an amount of the molten silicon to be supplied to the main crucible 120 (see FIG. 1) is small and low power energy is supplied, energy efficiency is improved. For example, when the molten silicon to be supplied to the main crucible 120 (see FIG. 1) is reduced from 170.6 g/min to 150 g/min, that is, when the molten silicon to be supplied to the main crucible 120 (see FIG. 1) is reduced by about 12%, as illustrated in FIG. 7, a standard (STD) melting time may be changed to a changed melting time which is reduced by 12%. Accordingly, the power energy for generating the molten silicon reduced to 150 g/min is reduced by about 12%.

As described above, the control unit 190 (see FIG. 2) adjusts the power energy supplied to the preliminary heater 155 (see FIG. 1) according to the amount of the molten silicon supplied to the main crucible 120 (see FIG. 1), and thus energy efficiency of the ingot growing apparatus is improved.

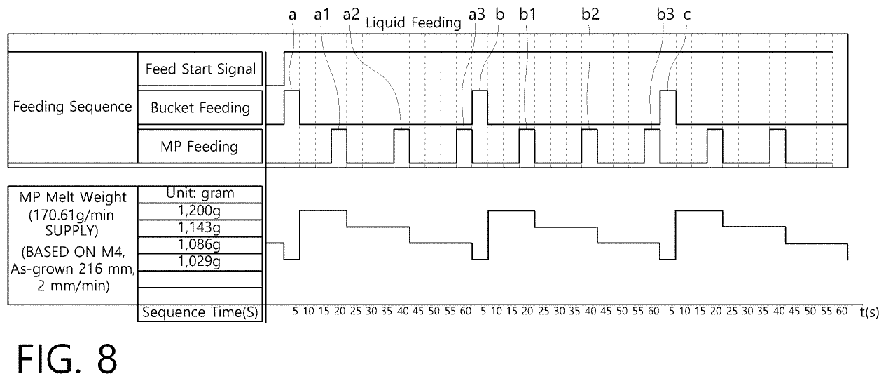

FIG. 8 is a view illustrating a supply pattern (feeding sequence) of a solid silicon material in the quantitative supply unit (bucket feeding) and a supply pattern (feeding sequence) of molten silicon in the preliminary crucible (MP feeding) supplied to the main crucible.

First, the control unit 190 (see FIG. 2) controls the quantitative supply unit (Bucket Feeding) 170 (see FIG. 1) and the preliminary crucible (MP Feeding) 151 (see FIG. 1) according to a supply start signal (Feed Start Signal).

The quantitative supply unit (Bucket Feeding) supplies a required amount of a quantitative solid silicon material determined by the control unit 190 (see FIG. 2) to the preliminary crucible (MP Feeding). That is, the required amount of the solid silicon material is controlled by the control unit 190 (see FIG. 2).

As illustrated in FIG. 8, the quantitative supply unit (Bucket Feeding) supplies a plurality of required amounts including a first required amount a, a second required amount b, and a third required amount c to the preliminary crucible (MP Feeding) at about one-minute intervals. In this case, the plurality of required amounts including the first required amount a, the second required amount b, and the third required amount c are, for example, about 170.61 g.

Meanwhile, the method of controlling the ingot growing apparatus according to the embodiment of the present invention includes the molten silicon accommodation maintenance operation S160 of controlling a state in which a predetermined amount or more of the molten silicon is accommodated in the preliminary crucible (MP Feeding) to be maintained. For example, in order to minimize power energy consumption for heating the preliminary crucible (MP Feeding), the preliminary crucible (MP Feeding) accommodates about 1,029 g of the molten silicon. Accordingly, in a state in which the preliminary crucible (MP Feeding) accommodates about 1,029 g of the molten silicon, the preliminary crucible (MP Feeding) receives and melts about 170.61 g of solid polysilicon, and thus accommodates about 1,200 g of the molten silicon.

In addition, the preliminary crucible (MP Feeding) supplies the molten silicon to the main crucible 120 (see FIG. 1) a plurality of times, for example, n times per minute. In this case, for example, when n is 3, the newly supplied 170.61 g of the solid polysilicon is melted, and then a total of 170.61 g is input to the main crucible 120 (see FIG. 1) three times, and when n is 1, the supplied 170.61 g of the solid polysilicon is melted, and then 170.61 g of the molten silicon is input to the main crucible 120 (see FIG. 1) once. Meanwhile, when n is smaller than 3, since a difference in temperature between the molten silicon supplied from the preliminary crucible (MP Feeding) and the silicon M molten in the main crucible is large, it is difficult to maintain a constant temperature for growing the ingot I. When n is 3 or more, there is a disadvantage that the preliminary crucible (MP Feeding) should be precisely driven to move a small amount of the molten silicon to the main crucible 120 (see FIG. 1), but a change in temperature of the molten silicon accommodated in the preliminary crucible (MP Feeding) is minimized, and when the molten silicon in the preliminary crucible (MP Feeding) is added to the molten silicon accommodated in the main crucible 120 (see FIG. 1), a change in temperature in a portion from which a single crystal of the ingot is grown may be minimized. Accordingly, according to the embodiment of the present invention, a yield of the single crystal of the ingot is improved by stably growing the ingot.

An ingot growing apparatus and a method of controlling the same according to an embodiment of the present invention can maintain a constant level of a surface of molten silicon accommodated in a main crucible by controlling the supply of molten silicon supplied to the main crucible according to a measured change in level of the surface of the silicon,

In addition, as a constant level of a surface of molten silicon accommodated in a main crucible is maintained, predetermined levels of quality and yield of an ingot can be managed.

In addition, since an amount of molten silicon supplied to a main crucible can be controlled while measuring a change in level of a surface of the molten silicon in real time, a decrease in yield of a single crystal of an ingot due to a delay in a growing process time or stopping the growing process of the ingot due to an excess/insufficient supply amount of the molten silicon is prevented.

While embodiments of the present invention have been described above, the spirit of the present invention is not limited to the embodiments proposed in this specification. Other embodiments may be easily suggested by adding, changing and removing components by those skilled in the art understanding the spirit of the present invention and will fall within the spirit and scope of the present invention.

What is claimed is:

1. An ingot growing apparatus comprising:
a growth furnace in which a main crucible is disposed, wherein the main crucible accommodates molten silicon to grow an ingot;
a preliminary crucible which receives a solid silicon material, melts the solid silicon material, and supplies molten silicon to the main crucible;
a measurement unit which is installed to pass through the growth furnace and measures a change in level of a surface of the molten silicon in the main crucible; and
a control unit which controls supply of the molten silicon in the preliminary crucible to the main crucible on the basis of the measured change in the level of the surface of the molten silicon.

2. The ingot growing apparatus of claim 1, wherein:
a reflector which blocks heat from being transferred to the ingot is provided at an upper side of the main crucible; and
the measurement unit measures the change in the level of the surface of the molten silicon through a change in gap between the surface of the molten silicon in the main crucible and a lower end of the reflector by measuring the surface of the molten silicon of the main crucible and the lower end of the reflector.

3. The ingot growing apparatus of claim 1, wherein the control unit calculates a change in level of the surface of the molten silicon in the main crucible on the basis of a diameter of the ingot, an upward pulling speed of the ingot, and a diameter of the main crucible.

4. The ingot growing apparatus of claim 3, wherein, when the measured change in the level of the surface of the molten silicon is greater than the calculated change in the level of the surface of the molten silicon, the control unit increases the molten silicon in the preliminary crucible supplied to the main crucible as much as a difference between the measured change in the level of the surface of the molten silicon and the calculated change in the level of the surface of the molten silicon.

5. The ingot growing apparatus of claim 3, wherein, when the measured change in the level of the surface of the molten silicon is smaller than the calculated change in the level of the surface of the molten silicon, the control unit decreases the molten silicon in the preliminary crucible supplied to the main crucible as much as a difference between the measured change in the level of the surface of the molten silicon and the calculated change in the level of the surface of the molten silicon.

6. The ingot growing apparatus of claim 2, wherein, when the surface of the molten silicon comes into contact with the lower end of the reflector, the control unit stops supplying the molten silicon in the preliminary crucible to the main crucible.

7. The ingot growing apparatus of claim 3, further comprising a weight measurement unit which measures a change in weight of the ingot per unit time,
wherein the control unit calculates a change in weight of the ingot per unit time on the basis of the diameter of the ingot and the upward pulling speed of the ingot, and
when the measured change in the weight of the ingot per unit time is greater than the calculated change in the weight of the ingot per unit time, the control unit increases the molten silicon in the preliminary crucible supplied to the main crucible as much as a difference between the measured change in the weight of the ingot per unit time and the calculated change in the weight of the ingot per unit time.

8. A method of controlling an ingot growing apparatus in which molten silicon in a preliminary crucible is supplied to a main crucible in which an ingot is grown, the method comprising:
a surface level change measurement operation in which a change in level of a surface of molten silicon in a main crucible is measured; and
a molten silicon supply control operation in which supply of molten silicon in a preliminary crucible to the main crucible is controlled on the basis of the measured change in the level of the surface of the molten silicon.

9. The method of claim 8, wherein in the surface level change measurement operation, the change in the level of the surface of the molten silicon is measured through a change in distance between the surface of the molten silicon in the main crucible and a lower end of a reflector provided above the main crucible by measuring the surface of the molten silicon of the main crucible and the lower end of the reflector.

10. The method of claim 8, further comprising a surface level change calculation operation in which a change in level of the surface of the molten silicon in the main crucible is calculated on the basis of a diameter of the ingot, an upward pulling speed of the ingot, and a diameter of the main crucible.

11. The method of claim 10, wherein the molten silicon supply control operation includes a first supply increase operation in which the molten silicon in the preliminary crucible supplied to the main crucible is increased as much as a difference between the measured change in the level of the surface of the molten silicon and the calculated change in the level of the surface of the molten silicon when the measured change in the level of the surface of the molten silicon is greater than the calculated change in the level of the surface of the molten silicon.

12. The method of claim 10, wherein the molten silicon supply control operation includes a supply reduction operation in which the molten silicon in the preliminary crucible supplied to the main crucible is reduced as much as a difference between the measured change in the level of the surface of the molten silicon and the calculated change in the level of the surface of the molten silicon when the measured change in the level of the surface of the molten silicon is smaller than the calculated change in the level of the surface of the molten silicon.

13. The method of claim 9, wherein the molten silicon supply control operation includes a supply stop operation in which the supply of the molten silicon in the preliminary crucible to the main crucible is stopped when the surface of the molten silicon comes into contact with the lower end of the reflector.

14. The method of claim 10, further comprising:
an ingot weight change measurement operation in which a change in weight of the ingot per unit time is measured; and
an ingot weight change calculation operation in which a change in weight of the ingot per unit time is calculated on the basis of the diameter of the ingot and the upward pulling speed of the ingot,
wherein in the molten silicon supply control operation, the supply of the molten silicon in the preliminary crucible to the main crucible is controlled on the basis of the measured change in the level of the surface of the molten silicon, the calculated change in the level of the surface of the molten silicon, the measured change in the weight of the ingot per unit time, and the calculated change in the weight of the ingot per unit time.

15. The method of claim 14, wherein the molten silicon supply control operation includes a second supply increase operation in which the molten silicon in the preliminary crucible supplied to the main crucible is increased as much as a difference between the measured change in the weight of the ingot per unit time and the calculated change in the weight of the ingot per unit time when the measured change in the weight of the ingot per unit time is greater than the calculated change in the weight of the ingot per unit time.

16. The method of claim 8, further comprising a power energy reduction operation in which power energy for heating the preliminary crucible is reduced when the supply of the molten silicon is reduced.

17. The method of claim 8, further comprising a molten silicon supply operation in which a required amount of a solid silicon material is melted and the molten silicon in the preliminary crucible is supplied to the main crucible a plurality times.

18. The method of claim 8, further comprising a molten silicon accommodation maintenance operation in which a state in which a predetermined amount or more of the molten silicon is accommodated in the preliminary crucible is maintained.
